(19) United States
(12) Patent Application Publication
(10) Pub. No.: US 2025/0369118 A1
(43) Pub. Date: Dec. 4, 2025

(54) SHOWERHEAD ASSEMBLIES, SEMICONDUCTOR PROCESSING SYSTEMS INCLUDING SHOWERHEAD ASSEMBIES, AND ASSOCIATED METHODS

(71) Applicant: ASM IP Holding B.V., Almere (NL)

(72) Inventor: Bryan Griffith, Chandler, AZ (US)

(21) Appl. No.: 19/218,965

(22) Filed: May 27, 2025

Related U.S. Application Data
(60) Provisional application No. 63/653,485, filed on May 30, 2024.

(51) Int. Cl. C23C 16/455; C23C 16/44

(52) U.S. Cl. CPC C23C 16/45565; C23C 16/4412

(57) ABSTRACT

Showerhead assemblies and semiconductor processing systems including showerhead assemblies are disclosed. The showerhead assemblies disclosed include a lid, a showerhead plate, and an annular flow ring disposed between the lid and the showerhead plate. Methods for regulating gas flow to and from a reaction chamber when performing a process are disclosed. The methods disclosed include positioning an annular flow ring at first position and a second position.

### CROSS-REFERENCE TO RELATED APPLICATIONS

This application is a nonprovisional of, and claims priority to and the benefit of, U.S. Provisional Patent Application No. 63/653,485, filed May 30, 2024 and entitled “SHOWERHEAD ASSEMBLIES, SEMICONDUCTOR PROCESSING SYSTEMS INCLUDING SHOWERHEAD ASSEMBLIES, AND ASSOCIATED METHODS,” which is hereby incorporated by reference herein.

### FIELD

The present disclosure relates generally to the field of semiconductor processing apparatus, associated processing methods, and to the field of device and integrated circuit manufacture. More particularly, the present disclosure generally relates to showerhead assemblies, semiconductor processing systems including such showerhead assemblies and associated methods of processing a substrate within a reaction chamber.

### BACKGROUND

A showerhead assembly may be used during a deposition process to provide uniform gas flow onto a substrate supported within a reaction chamber. However, due to a limited exhaust path through common showerhead assemblies, an effective purge of the reaction chamber can be difficult to achieve within a desired time period.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to showerhead assemblies, semiconductor processing systems including showerhead assemblies, and methods for regulating gas flow to and from a reaction chamber when performing a process.

According to one aspect, a showerhead assembly comprises: a lid comprising an upper lid surface and a lower lid surface, the lower lid surface including an exhaust channel; a showerhead plate disposed beneath the lid and having a plate central axis, the showerhead plate including: a plurality of inner through-holes extending through the showerhead plate from an upper plate surface to a lower plate surface, the plurality of inner through-holes positioned in an inner region of the showerhead plate concentric to the plate central axis; and a plurality of outer through-holes disposed in a concentric ring around the inner region and extending through the showerhead plate from the upper plate surface to the lower plate surface, the plurality of outer through-holes positioned at a first radial distance from the plate central axis; and an annular flow ring disposed between the lid and the showerhead plate and having a ring central axis coincident with the plate central axis, the annular flow ring comprising: a plurality of exhaust through-holes disposed in a concentric ring at the first radial distance from the ring central axis and extending through the annular flow ring from an upper ring surface to a lower ring surface; wherein adjacent through-holes of the plurality of exhaust through-holes alternate in sequence between a first diameter and a second diameter, the first diameter being less than the second diameter.

In one embodiment of the showerhead assembly, adjacent through-holes of the plurality of outer through-holes are separated by a first arc length, and adjacent through-holes of the plurality of exhaust through-holes are separated by a second arc length, wherein the second arc length is half the radial distance of the first arc length.

In one embodiment of the showerhead assembly, the annular flow ring has an inner radius greater than a radius of the inner region of the showerhead plate.

In one embodiment of the showerhead assembly, the exhaust channel of the lid, the plurality of outer through-holes of the showerhead plate, and the plurality of exhaust through-holes of the annular flow ring are radially aligned with each other.

In one embodiment of the showerhead assembly, the annular flow ring further comprising an actuator coupling constructed and arranged to couple with an actuator device, the actuator device configured to rotate the annular flow ring about the ring central axis from a first position to a second position.

In one embodiment of the showerhead assembly, the plurality of exhaust through-holes having the first diameter are configured to align with the plurality of outer through-holes of the showerhead plate at the first position, and the plurality of exhaust through-holes having the second diameter are configured to align with the plurality of outer through-holes of the showerhead plate at the second position.

According to another aspect, a semiconductor processing system comprises: a reaction chamber; a showerhead assembly configured to regulate gas flow to and from the reaction chamber, the showerhead assembly comprising: a lid comprising an upper lid surface and a lower lid surface, the upper lid surface comprising a main inlet configured to couple with a gas source, and the lower lid surface comprising an exhaust channel; a showerhead plate disposed beneath the lid and having a plate central axis, the showerhead plate comprising: a plurality of inner through-holes extending through the showerhead plate from an upper plate surface to a lower plate surface, the plurality of inner through-holes positioned in an inner region of the showerhead plate concentric to the plate central axis; and a plurality of outer through-holes disposed in a concentric ring around the plurality of inner through-holes and extending through the showerhead plate from the upper plate surface to the lower plate surface, the plurality of outer through-holes positioned at a first radial distance from the plate central axis; and an annular flow ring disposed between the lid and showerhead plate and having a ring central axis coincident with the plate central axis, the annular flow ring comprising: an actuator coupling disposed on a surface of the annular flow ring; and a plurality of exhaust through-holes disposed in a concentric ring at the first radial distance from the ring central axis and extending through the annular flow ring from an upper ring surface to a lower ring surface; wherein the plurality of exhaust through-holes alternate in sequence between a first diameter and a second diameter, the first diameter being less than the second diameter; an actuator device coupled to the actuator coupling, the actuator device configured to rotate the annular flow ring about the ring central axis from a first position to a second position; a valve manifold constructed and arranged to control a supply of gas to the showerhead assembly from the gas source; a vacuum assembly coupled to the exhaust channel and constructed and arranged for exhausting gas from the reaction chamber; and a control system constructed and arranged to synchronize the actuator device and a valve manifold.

In one embodiment of the semiconductor processing system, adjacent through-holes of the plurality of outer through-holes are separated by a first arc length, and adjacent through-holes of the plurality of exhaust through-holes are separated by a second arc length, wherein the second arc length is half of the first arc length.

In one embodiment of the semiconductor processing system, the annular flow ring has an inner radius greater than a radius of the inner region of the showerhead plate.

In one embodiment of the semiconductor processing system, the exhaust channel, the plurality of outer through-holes of the showerhead plate, and the plurality of exhaust through-holes of the annular flow ring are radially aligned with each other.

In one embodiment of the semiconductor processing system, the actuator device comprises an actuated two-state valve, wherein a first valve state positions the annular flow ring at the first position and a second valve state positions the annular flow ring at the second position.

In one embodiment of the semiconductor processing system, the plurality of exhaust through-holes having the first diameter are configured to align with the plurality of outer through-holes of the showerhead plate at the first position, and the plurality of exhaust through-holes having the second diameter are configured to align with the plurality of outer through-holes of the showerhead plate at the second position.

According to another aspect a method of regulating gas flow to and from a reaction chamber when performing a process comprises: at a showerhead assembly comprising an annular flow ring disposed between a lid and a showerhead plate, the annular flow ring including a plurality of exhaust through-holes disposed in a concentric ring at a first radial distance from a ring central axis and extending through the annular flow ring from an upper ring surface to a lower ring surface, the plurality of exhaust through-holes alternating in sequence between a first diameter and a second diameter, the first diameter being less than the second diameter; positioning the annular flow ring at a first position such that the first diameter through-holes are aligned with a plurality of outer through-holes extending through the showerhead plate; introducing a process gas into the reaction chamber; positioning the annular flow ring at a second position such that the second diameter through-holes are aligned with the plurality of outer through-holes extending through the showerhead plate; and purging the reaction chamber.

In one embodiment of the method, positioning the annular flow ring comprises actuating an actuator device coupled to the annular flow ring by an actuator coupling disposed on a surface of the annular flow ring, the actuator device configured to rotate the annular flow ring about the ring central axis from the first position to the second position.

In one embodiment of the method, adjacent through-holes of the plurality of outer through-holes are separated by a first arc length, and adjacent through-holes of the plurality of exhaust through-holes are separated by a second arc length, wherein the second arc length is half of the first arc length.

In one embodiment of the method, positioning the annular flow ring further comprises rotating the annular flow ring about the ring central axis by the second arc length.

In one embodiment of the method, the steps of positioning the annular flow ring at the first position, introducing the process gas into the reaction chamber, positioning the annular flow ring at the second position, and purging the reaction chamber are performed one or more times.

In one embodiment of the method, the process comprises an atomic layer deposition process.

In one embodiment of the method, the method further comprises positioning the annular flow ring at the first position prior to performing a pulsing step of the atomic layer deposition process.

In one embodiment of the method, the method further comprises positioning the annular flow ring at the second position prior to performing a pulsing step of the atomic layer deposition process.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a block diagram in accordance with one or more embodiments of the disclosure.

FIG. 2 illustrates a cross-sectional view of an exemplary reactor in accordance with one or more embodiments of the disclosure.

FIG. 3 illustrates an exploded view of an exemplary showerhead assembly in accordance with one or more embodiments of the disclosure.

FIG. 4 illustrates a top-down view of an exemplary showerhead plate in accordance with one or more embodiments of the disclosure.

FIG. 5 illustrates a top-down view of an exemplary annular flow ring in accordance with one or more embodiments of the disclosure.

FIG. 6 illustrates an exemplary semiconductor processing system including a showerhead assembly in accordance with one or more embodiments of the disclosure.

FIG. 7 illustrates an exemplary process for regulating gas flow to and from a reaction chamber when performing a process in accordance with one or more embodiments of the disclosure.

FIG. 8 illustrates a plan view cutaway of a portion of a showerhead assembly with an annular flow ring at a first position in accordance with one or more embodiments of the disclosure.

FIG. 9 illustrates a plan view cutaway of a portion of a showerhead assembly with an annular flow ring at a second position in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

Various embodiments of the present disclosure relate to showerhead assemblies, semiconductor processing systems including such showerhead assemblies, and associated methods for processing substrates.

Commonly utilized showerhead assemblies can include a first series of through-holes (i.e., apertures) through which process gas is introduced into an associated reaction chamber (i.e., gas introduction through-holes) and a second series of through-holes through which excess process gas, inactive gas (e.g., purge gases, carrier gases), and any reaction by-products are exhausted from the reaction chamber (i.e., gas exhaust through-holes). The dimensions (e.g., the diameter) of such through-holes are normally fixed and are determined by the mechanical processes employed in fabricating the through-holes. However, having fixed dimensioned through-holes can detrimentally effect substrate processing when utilizing certain processing methods.

As a non-limiting example, atomic layer deposition (ALD) processes commonly comprise a two step process where (a) process gas (e.g., precursors/reactants and the like) is introduced into the reaction chamber through the showerhead assembly (commonly referred as the pulsing step) and (b) excess process gas and any reaction by-products are exhausted from the reaction chamber through the showerhead assembly (commonly referred to as the purging step). In certain examples, during the pulsing step the process gas resides within a reaction space within the reaction chamber for an adequate time period to allow saturation of the surface of the substrate and/or completion of reactions with an absorbed species on the substrate. During the purging step the excess process gas and any reaction byproducts are normally removed as rapidly as possible so that the cycle time of the ALD process and hence the through-put and/or deposition rate is optimized. However, in such examples, the fixed dimensioned gas exhaust through-holes of the showerhead assembly are not optimized for both process gas residence within the reaction chamber as well as rapid purging of the reaction chamber. For example, rapid purging of the reaction chamber may be achieved employing gas exhaust through-holes with a large dimension such that a high conductance path is employed to rapidly remove gas from the reaction chamber. In contrast, when employing gas exhaust through-holes optimized for the purging step (e.g., with a large dimension) during the pulsing step, the process gas may have insufficient residence time within the reaction space resulting incomplete saturation/reactions, ineffective utilization of the processes gas, and a reduce lifetime and efficiency of apparatus and components downstream of the reaction chamber.

Therefore, the various embodiments of the disclosure provide a showerhead assembly including an annular flow ring which is disposed between a lid of the assembly (which includes an exhaust channel) and a showerhead plate (which includes the gas introduction through-holes and the gas exhaust through-holes). In various embodiments, the annular flow ring comprises a plurality of exhaust through-holes which alternate in sequence between a first dimension (e.g., optimized for the pulsing step) and a second dimension (e.g., optimized for the purging step). In various embodiments, the annular flow ring can be coupled with an actuator device which can be triggered by a control system to rotate the annular flow ring such that the exhaust through-holes optimized for the pulsing step are aligned with the showerhead plate exhaust through-holes during the pulsing step, and subsequently triggered by the control system to rotate the annular flow ring such that exhaust through-holes optimized for the purging step are aligned with the showerhead plate exhaust through-holes during the purging step.

The present technology may be described in terms of functional block components and various processing steps. Such functional blocks may be realized by any number of components configured to perform the specified functions and achieve the various results. For example, the present technology may employ various reaction chambers, susceptors, valves, precursors, and delivery lines.

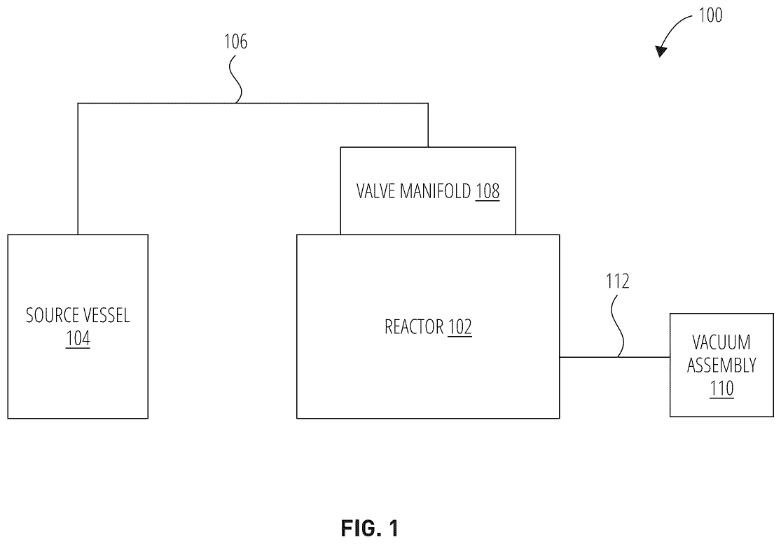

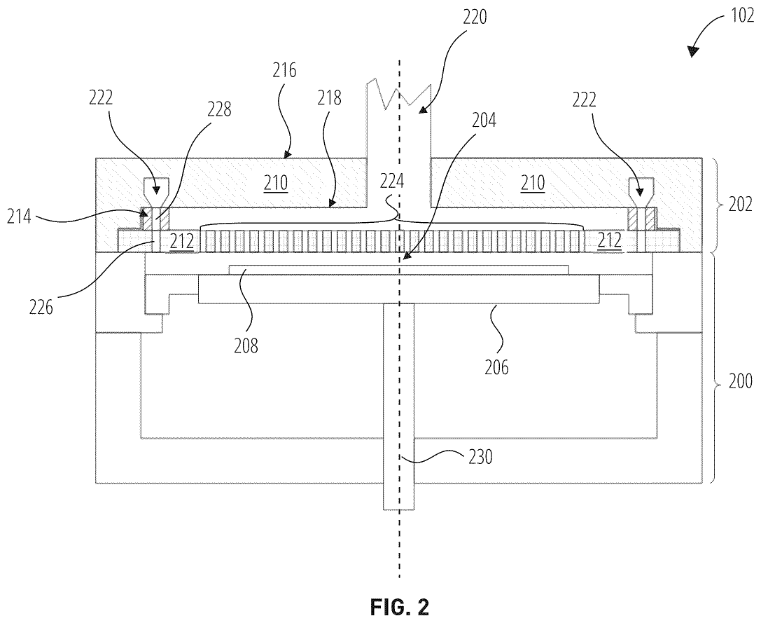

Turning now to the figures, FIG. 1 illustrates an exemplary semiconductor processing system 100 including a reactor 102 configured to process a substrate (e.g., the substrate 208 of FIG. 2). The reactor 102 may be configured to deposit a layer on a substrate, perform etching, and the like. The semiconductor processing system 100 may further comprise a source vessel 104 configured to contain or hold a chemistry (e.g., a precursor/reactant, an inactive gas, and the like) used in a semiconductor manufacturing process. The chemistry in the source vessel 104 may be in a solid, liquid, or gas phase initially. In the case of a solid or a liquid chemistry, the solid or liquid may be converted to a gas phase. For example, the source vessel 104 may comprise various devices and/or systems to convert a solid or a liquid to a gas. The conversion to a gas phase may occur within the source vessel 104. In addition, the semiconductor processing system 100 may further comprise a gas line 106 to transport the gas to the reactor 102. For example, the gas line 106 may be coupled to the source vessel 104 at a first end and the reactor 102 at a second end. In various embodiments, the semiconductor processing system 100 may further comprise a valve manifold 108 configured to provide controlled flow and mixing of multiple gas sources prior to entry into the reactor 102. The valve manifold 108 may be coupled directly to the reactor 102 and may be coupled to the gas line 106 and configured to receive the gas from the source vessel 104. In addition, the semiconductor processing system 100 may include a vacuum assembly 110 in fluid communication with the reactor 102 by a vacuum line 112. The vacuum assembly 110 (and associated vacuum line 112) can be employed to remove excess chemistry and reaction by-products from reactor 102 as well as controlling the pressure within the reactor 102.

FIG. 2 illustrates a cross sectional view of the reactor 102 of FIG. 1 and demonstrates an exemplary internal configuration of the various components and assemblies within the reactor 102. It should be noted the following description with reference to FIG. 2 illustrates in brief the spatial relationship of the various components within the reactor 102 and particularly the components comprising the showerhead assemblies of the present disclosure.

Referring to FIG. 2, the reactor 102 may comprise a reaction chamber 200 and a showerhead assembly 202 positioned above the reaction chamber 200. The reaction chamber 200 may comprise a reaction space 204 and a substrate support 206 (such as a susceptor) configured to support a substrate 208.

In accordance with examples of the disclosure, the showerhead assembly 202 may comprise a lid 210, a showerhead plate 212, and an annular flow ring 214 disposed between the lid 210 and the showerhead plate 212. In brief, the lid 210 of showerhead plate 212 comprises an upper lid surface 216 and a lower lid surface 218. The upper lid surface 216 comprises a main inlet 220 configured to fluidically couple with a gas source via a valve manifold (such as supplied from source vessel 104 of FIG. 1). In addition, the lid 210 comprises an exhaust channel 222 disposed in the lower lid surface 218, as discussed in greater detail below. In some embodiments, the exhaust channel 222 is in fluid communication with a vacuum assembly by means of a vacuum line (such as exemplary vacuum assembly 110 and vacuum line 112 of FIG. 1).

In various embodiments, the showerhead assembly 202 also comprises a showerhead plate 212 disposed beneath the lid 210. The showerhead plate 212 comprises a plurality of inner through-holes 224 and a plurality of outer through-holes 226, as described in greater detail below.

In various embodiments, the showerhead assembly 202 also includes the annular flow ring 214 disposed between the lid 210 and the showerhead plate 212. As described in greater detail below, the annular flow ring 214 can comprise a plurality of exhaust through-holes 228. In various embodiments, the plurality of exhaust through-holes 228 alternate in sequence radially around the annular flow ring 214 between a first diameter and a second diameter, wherein the first diameter is less than the second diameter. The alternating diameters of the plurality of exhaust through-holes 228 in the annular flow ring 214 can be utilized to modulate the size of the exhaust path from the reaction space 204 within reaction chamber 200 to the exhaust channel 222, as described in greater detail below.

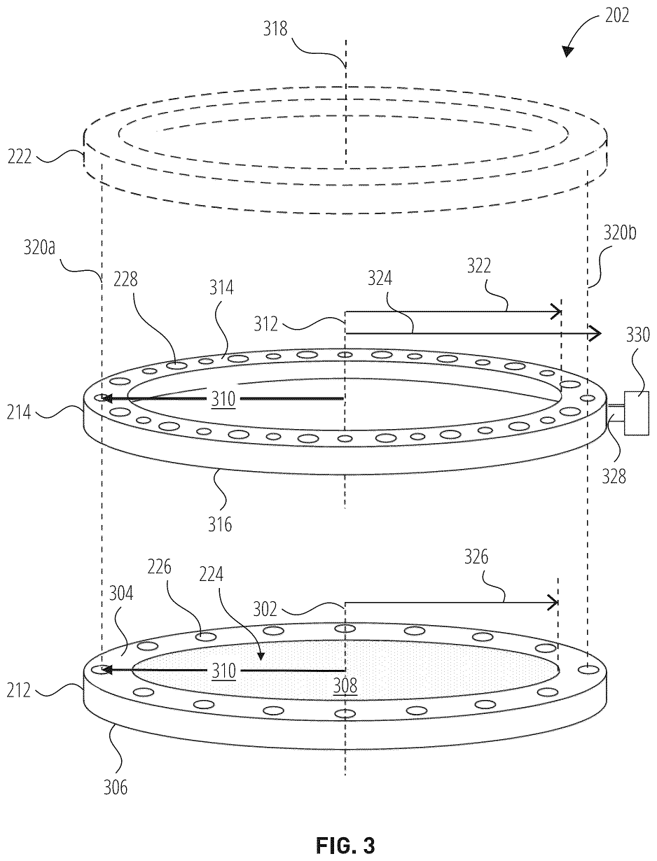

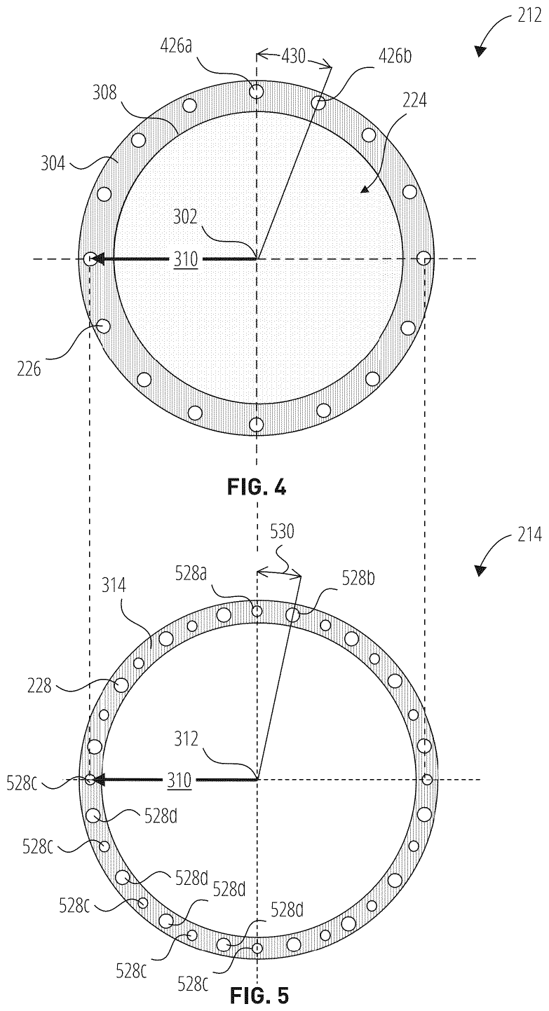

FIG. 3 illustrates an exploded view of the showerhead assembly 202 (of FIG. 1) where the horizontal positioning of the components has been retained and the vertical separation between the exhaust channel 222 (disposed within the lower lid surface 218 of the lid 210 of FIG. 2), the annular flow ring 214, and the showerhead plate 212 has been expanded to more clearly illustrate the components of the showerhead assembly 202. In addition, FIG. 4 and FIG. 5 illustrate top-down views of the showerhead plate 212 and the annular flow ring 214, respectively.

In accordance with examples of the disclosure and with reference to FIG. 3, the showerhead assembly 202 includes a lid comprising an exhaust channel 222 (the lid 210 of FIG. 2 is omitted in FIG. 3 to better illustrate the exhaust channel 222 and the exhaust channel is illustrated by dashed lines to indicate it is disposed internally within the lower lid surface of the lid)

In various embodiments, the showerhead assembly 202 comprises a showerhead plate 212 disposed beneath the lid and having a plate central axis 302, as illustrated in FIG. 3 and FIG. 4.

In accordance with examples of the disclosure, the showerhead plate 212 may comprise a plurality of inner through-holes 224 extending through the showerhead plate 212 from an upper plate surface 304 to a lower plate surface 306. In such examples, the plurality of inner through-holes 224 may be position in an inner region 308 of the showerhead plate 212, the inner region 308 being concentric to the plate central axis 302. As a non-limiting example, the plurality of inner through-holes 224 of the showerhead plate 212 can be employed for introducing process gas into the reaction chamber (i.e., the plurality of inner through-holes 224 comprise gas introduction through-holes).

In accordance with further examples of the disclosure, the showerhead plate 212 may comprise a plurality of outer through-holes 226 disposed in a concentric ring around the inner region 308 and extending through the showerhead plate 212 from the upper plate surface 304 to the lower plate surface 306. In such examples, the plurality of outer through-holes 226 may be positioned at a first radial distance 310 from the plate central axis 302. In further examples, adjacent through-holes of the plurality of outer through-holes (such as exemplary adjacent outer through-holes 426a and 426b of FIG. 4) can be radially separated by a first arc length 430. As a non-limiting example, the plurality of outer through-holes 226 of the showerhead plate 212 can be employed for exhausting process gas (and any reaction byproducts) from reaction chamber 200 (i.e., the plurality of outer through-holes 226 comprise gas exhaust through-holes).

In various embodiments, the showerhead assembly 202 also comprises an annular flow ring 214. In accordance with examples of the disclosure, the annular flow ring 214 is disposed between the exhaust channel 222 (within the lower lid surface of the lid 210 of FIG. 2) and the showerhead plate 212, as illustrated in FIG. 2 and FIG. 3.

In accordance with examples of the disclosure and with reference to FIG. 3 and FIG. 5, the annular flow ring 214 comprises a ring central axis 312. In some embodiments, the ring central axis 312 (of the annular flow ring 214) is coincident with the plate central axis 302 (of the showerhead plate 212), or in other words the ring central axis 312 (of the annular flow ring 214) and the plate central axis 302 (of the showerhead plate 212) are aligned with one another.

In addition, in various exemplary embodiments the exhaust channel 222 comprises an annular exhaust channel which extends into the lower lid surface 218 of the lid 210 of FIG. 2. In such embodiments, the annular exhaust channel may have a channel central axis 318 (see FIG. 3). For example, the channel central axis 318 can be coincident with both the ring central axis 312 and the plate central axis 302, such that the central axes of the exhaust channel 222, the annular flow ring 214, and the showerhead plate are aligned with one another. In some embodiments, the components of the showerhead assembly 202 (e.g., the exhaust channel 222 within the lid 210, the annular flow ring 214, and the showerhead plate 212) together have a common showerhead assembly central axis 230, as illustrated in FIG. 2.

In accordance with examples of the disclosure, the annular flow ring 214 comprises a plurality of exhaust through-holes 228. For example, the plurality of exhaust through-holes 228 can extend from an upper ring surface 314 to a lower ring surface 316 as illustrated in FIG. 3. In accordance with examples of the disclosure, the plurality of exhaust through-holes 228 may be disposed in a concentric ring around the ring central axis 312. In such examples, the plurality of exhaust through-holes 228 may be positioned at a first radial distance 310 from the ring central axis 312, as illustrated in FIG. 3 and FIG. 5. Therefore, and as illustrated in FIG. 3, both the central axes of the annular flow ring 214 and the showerhead plate 212 (i.e., axes 302 and 304) are coincident (i.e., aligned) and the plurality of outer through-holes 226 (of the showerhead plate 212) and the plurality of exhaust through-holes 228 (of the annular flow ring 214) are both positioned at a first radial distance 310 from the coincident axes (i.e., axes 302 and 304) such that the plurality of outer through-holes 226 and the plurality of exhaust through-holes 228 are radially aligned with each other. The radial alignment of the plurality of outer through-holes 226 (of the showerhead plate) and the plurality of exhaust through-holes 228 (of the annular flow ring 214) are clearly illustrated in FIG. 3 where alignment marks 320a and 320b illustrate the alignment. In some embodiments, and as illustrated in FIG. 3, the exhaust channel 222 within the lower lid surface may also be radially aligned with the plurality of outer through-holes 226 (of the showerhead plate 212) and the plurality of exhaust through-holes 228 (of the annular flow ring 214). Therefore, in some embodiments, the exhaust channel 222 within the lid (e.g., 210 of FIG. 2), the plurality of outer through-holes 226 (of the showerhead plate 212) and the plurality of exhaust through-holes 228 of the annular flow ring are radially aligned with each other.

In accordance with examples of the disclosure, adjacent through-holes of the plurality of exhaust through-holes 228 in the annular flow ring 214 (such as exemplary adjacent exhaust through-holes 528a and 528b of FIG. 5) are separated radially by a second arc length 530, wherein the second arc length 530 is half the radial distance of the first arc length 430 (FIG. 4). In other words, the radial distance between adjacent through-holes extending through the annular flow ring 214 (e.g., through-holes 228) is half that of the radial distance between adjacent through-holes extending through the showerhead plate 212.

In accordance with examples of the disclosure, adjacent through-holes of the plurality of exhaust through-holes 228 in the annular flow ring 214 (such as exemplary adjacent pairs of exhaust through-holes 528c and 528d) alternate in sequence between a first diameter (e.g., the diameter of 528c) and a second diameter (e.g., the diameter of 528b), wherein the first diameter is less than the second diameter. As a non-limiting example, the exemplary exhaust through-holes 528c can be dimensionally optimized and aligned with the plurality of outer through-holes of the showerhead plate during pulsing operations in an ALD process, and the exemplary exhaust through-holes 528d can be dimensionally optimized and aligned with the plurality of outer through-holes 226 of the showerhead plate 212 during purging operations in an ALD process. In some embodiments the first diameter through-holes may have a diameter the same, or substantially the same as the diameter of the plurality of outer through-holes of the showerhead plate. In some embodiments the second diameter through-holes may have a diameter less than the diameter of the plurality of outer through-holes of the showerhead plate.

In accordance with examples of the disclosure, the annular flow ring has an inner radius greater than a radius of the inner region of the showerhead plate. As previously described, the showerhead plate 212 comprises the plurality of inner through-holes 224 which can be positioned in the inner region 308 which can be concentric to the plate central axis 302 (see FIG. 3). In various embodiments, the plurality of inner through-holes 224 can be employed for introducing process gas into the reaction chamber (e.g., through-holes 224 comprise gas introduction through-holes). To allow the process gas to flow unobstructed through the showerhead assembly from the lid through the plurality of inner through-holes 224 of the showerhead plate 212 and on into the reaction chamber, the annular flow ring 214 can be constructed and arranged to maintain a free gas flow path through the showerhead assembly.

Therefore, in accordance with examples of the disclosure, the annular flow ring 214 (see FIG. 3) comprises an outer radius 324, an inner radius 322, and an annular ring width defined by the difference between the outer radius 324 and inner radius 322. In such examples, the inner radius 322 of the annular flow ring 214 is greater than the radius of the inner region of the showerhead plate (i.e., radius 326). Therefore, the plurality of inner through-holes 224 positioned within the inner region 308 are unobstructed by the annular flow ring 214.

In accordance with examples of the disclosure, the annular flow ring further comprising an actuator coupling. In such examples and as illustrated in FIG. 3, the annular flow ring 214 comprises an actuator coupling 328 which enables a mechanical connection between the main body of the annular flow ring 214 and an actuator device 330. In some embodiments, the actuator device 330 can be configured to rotate the annular flow ring 214 about the ring central axis 312 from a first position to a second position, as described in greater detail below.

The various embodiments of the disclosure also provide semiconductor processing systems and particularly semiconductor processing systems including the showerhead assemblies as described above.

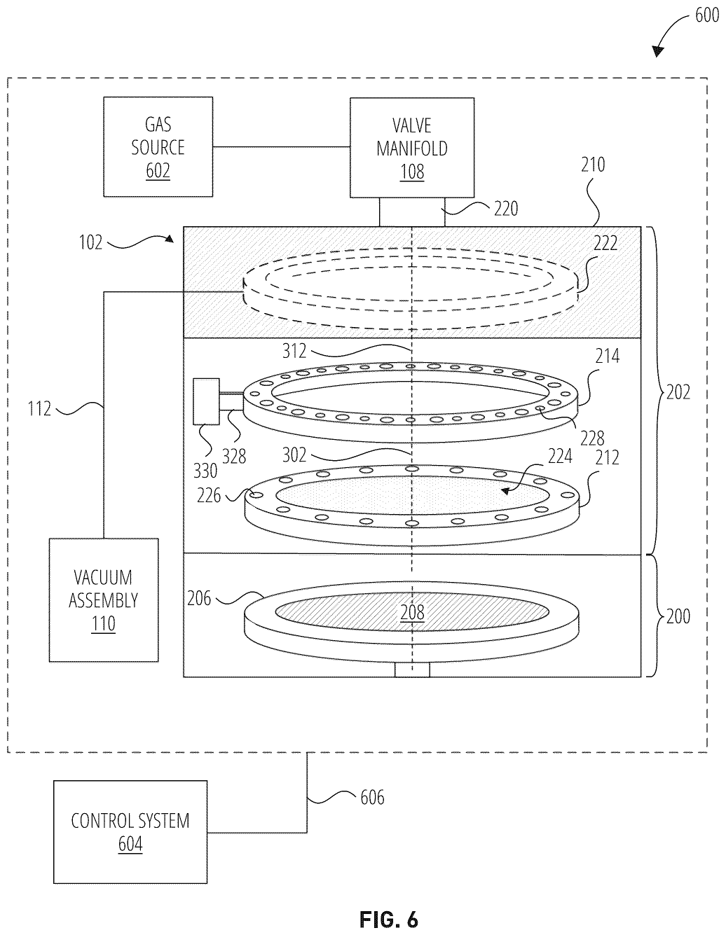

In accordance with examples of the disclosure, FIG. 6 illustrates an exemplary semiconductor processing system 600 including a showerhead assembly 202. In various embodiments the semiconductor processing system 600 comprises a reactor 102, a reaction chamber 200, and a showerhead assembly 202 disposed above the reaction chamber 200. In some embodiments, the showerhead assembly 202 is configured to control gas flow to and from the reaction chamber 200.

In accordance with examples of the disclosure, the showerhead assembly 202 of FIG. 6 comprises a lid 210 (as previously described) comprising an upper lid surface and a lower lid surface. In some embodiments the upper lid surface of the lid 210 comprising a main inlet 220 configured to couple with a gas source 602 via a valve manifold 108, and the lower lid surface comprising an exhaust channel 222 configured to couple with a vacuum assembly 110 via a vacuum line 112.

In accordance with examples of the disclosure, the showerhead assembly 202 of semiconductor processing 600 (FIG. 6) comprises a showerhead plate 212 disposed beneath the lid 210 and having a plate central axis 302. As previously described, the showerhead plate 212 can comprises a plurality of inner through-holes 224 extending through the body of showerhead plate 212, the plurality of inner through-holes 224 positioned in an inner region concentric to the plate central axis. In some embodiments, the showerhead plate 212 also comprises a plurality of outer through-holes 226 disposed in a concentric ring around the plurality of inner through-holes 224 and extending the body of the showerhead plate 212, the plurality of outer through-holes 226 being positioned at a first radial distance from the plate central axis, as previously described with reference FIG. 3 and FIG. 4.

In accordance with examples of the disclosure, the showerhead assembly 202 of semiconductor processing 600 (FIG. 6) comprises an annular flow ring 214 disposed between the lid 210 and showerhead plate 212 and having a ring central axis 312 coincident with the plate central axis 302. In such examples, the annular flow ring 214 comprises a plurality of exhaust through-holes 228 disposed in a concentric ring at the first radial distance from the ring central axis 312 and extending the body of annular flow ring 214, as described previously with reference to FIG. 3 and FIG. 5. The plurality of exhaust through-holes 228 may alternate in sequence between a first diameter and a second diameter, the first diameter being less than the second diameter, as described previously.

In accordance with examples of the disclosure, the annular flow ring 214 can also comprising an actuator coupling 328 disposed on a surface of the annular flow ring 214. In such examples, the actuator coupling 328 can be configured for coupling with an actuator device 330. In one aspect, the actuator device 330 comprises an actuated two-state valve, wherein a first valve state positions the annular flow ring 214 at a first position and a second valve state positions the annular flow ring 214 at the second position. In another aspect, the actuator device 330 comprises a continuous rotation actuator which provides continuous rotation to the annular flow ring 214 such that first diameter through-holes align with the plurality of inner through-holes 224 in the showerhead plate during a first time period and such that the second through-holes align with the plurality of inner through-holes 224 in the showerhead plate 212 at a second time period. In another aspect, the actuator device 330 comprises a stepper device which provides stepped rotation to the annular flow ring 214 such that first diameter through-holes align with the plurality of inner through-holes 224 in the showerhead plate during a first time period and such that the second through-holes align with the plurality of inner through-holes 224 in the showerhead plate 212 at a second time period.

In accordance with examples of the disclosure, the semiconductor processing system 600 comprises a valve manifold 108 constructed and arranged to control a supply of gas to the showerhead assembly from the gas source 602.

In accordance with examples of the disclosure, the semiconductor processing system 600 comprises a control system 604 constructed and arranged to operate/control various components and assemblies of semiconductor processing system 600. In one aspect, the control system 604 is configured to synchronize the actuator device and the valve manifold, as described in greater detail below with reference to method and processes associated with semiconductor processing system 600.

The various embodiments of the disclosure also provide methods for regulating gas flow to and from a reaction chamber when performing a process in a semiconductor processing systems and particularly semiconductor processing systems including the showerhead assemblies as described above.

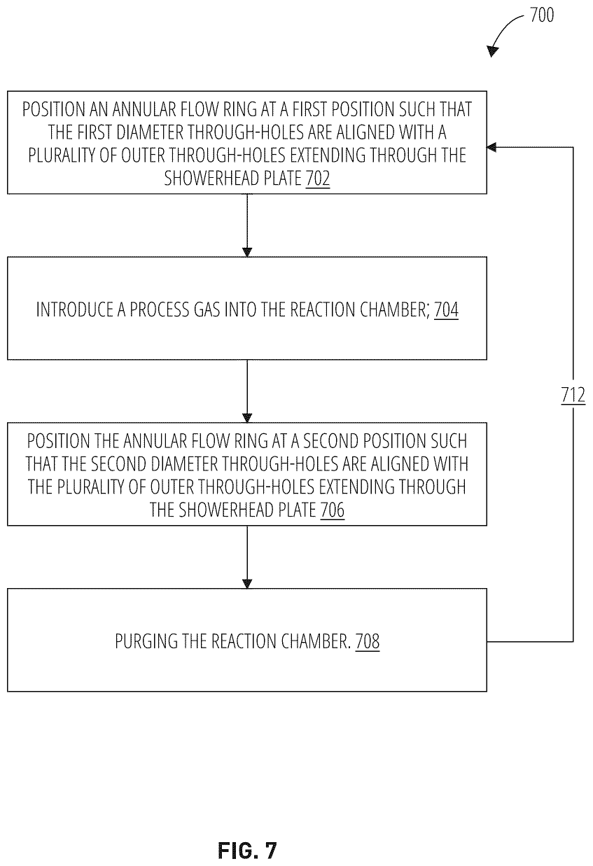

In accordance with examples of the disclosure, FIG. 7 illustrates an exemplary process 700 for regulating gas flow to and from a reaction chamber of a semiconductor processing system, such as, for example, semiconductor processing system 600 (FIG. 6) comprising a showerhead assembly 202 (FIG. 3).

In accordance with examples of the disclosure, process 700 (FIG. 7) comprises performing a method for regulating gas flow to and from a reaction chamber comprising a showerhead assembly showerhead assembly including an annular flow ring disposed between a lid and a showerhead plate, the annular flow ring including a plurality of exhaust through-holes disposed in a concentric ring at a first radial distance from a ring central axis and extending through the annular flow ring from an upper ring surface to a lower ring surface, the plurality of exhaust through-holes alternating in sequence between a first diameter and a second diameter, the first diameter being less than the second diameter (as described above).

In accordance with examples of the disclosure, process 700 (FIG. 7) can comprise positioning the annular flow ring at a first position such that the first diameter through-holes are aligned with a plurality of outer through-holes extending through the showerhead plate (step 702).

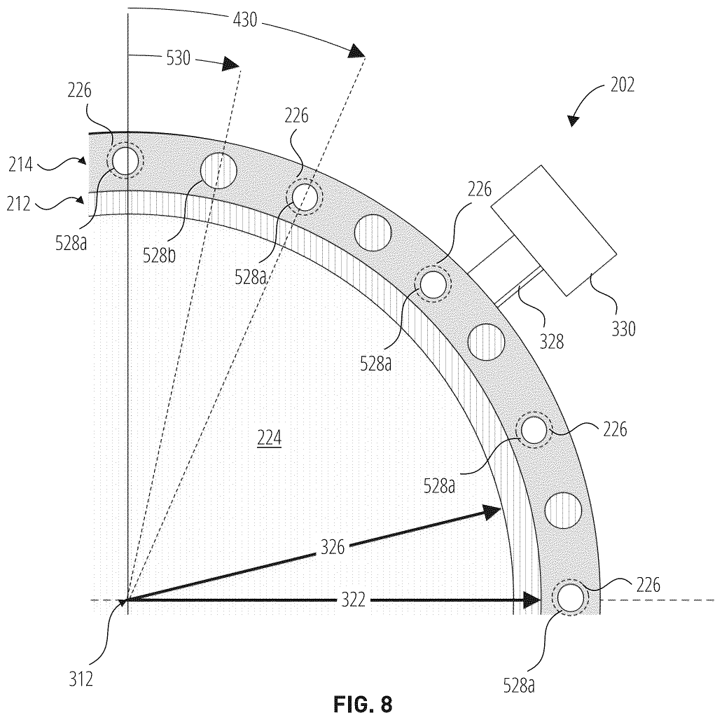

In further detail, FIG. 8 illustrates a plan view cutaway of a portion of the showerhead assembly 202 showing the annular flow ring 214 (above the showerhead plate 212) in the first position, where the dashed circles indicate exhaust through-holes of the showerhead plate 212 obscured by the annular flow ring 214. As illustrated in FIG. 8 the annular flow ring 214 is rotational positioned (at the first position) such that the first diameter through-holes 528a are aligned with the plurality of outer through-holes 226 of the showerhead plate 212. In accordance with examples of the disclosure, when the annular flow ring 214 is rotational positioned at the first position (as illustrated in FIG. 8) the gas conductance path to the aligned exhaust channel (not shown) can be reduced thereby allowing sufficient time for a process gas (introduced in a subsequent step of process 700) to interact with the substrate.

In accordance with examples the disclosure, positioning the annular flow ring comprises actuating an actuator device 330 coupled to the annular flow ring 214 by an actuator coupling 328 disposed on a surface of the annular flow ring, as illustrated in FIG. 8. In such examples, the actuator device 330 can be configured to rotate the annular flow ring 214 about the ring central axis.

In accordance with examples of the disclosure, process 700 (FIG. 7) can further comprise introducing a process gas into the reaction chamber (step 704). In such examples, the process gas can comprise a precursor/reactant which interacts with a substrate supported within the reaction chamber. In such examples, the positioning of the annular flow ring 214 at the first position (as illustrated in FIG. 8) allows a sufficient residence of the process gas in the reaction space within the reaction chamber wherein the process gas interacts with the substrate (e.g., absorbs, reacts, and the like).

In accordance with examples of the disclosure, process 700 (FIG. 7) can further comprise positioning the annular flow ring at a second position such that the second diameter through-holes are aligned with the plurality of outer through-holes extending through the showerhead plate (step 706).

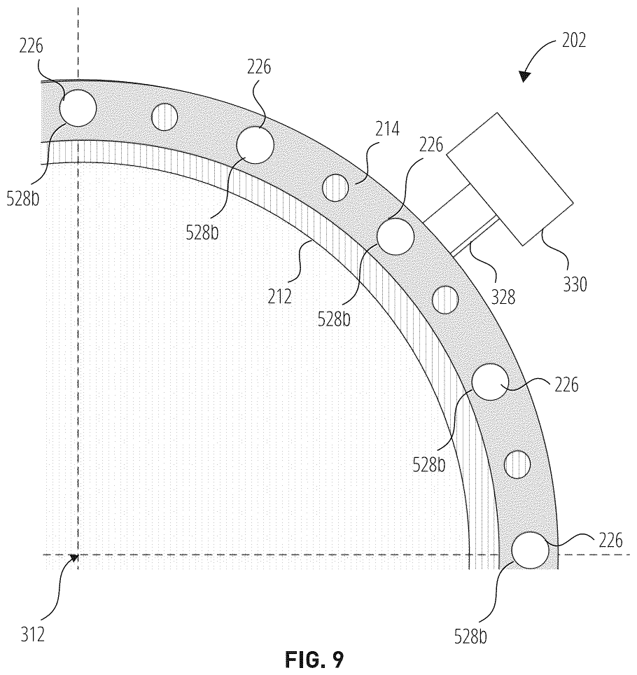

FIG. 9 illustrates a plan view cutaway of a portion of the showerhead assembly 202 showing the annular flow ring 214 (above the showerhead plate 212) in the second position. As illustrated in FIG. 9 the annular flow ring 214 is rotational positioned (at the second position) such that the second diameter through-holes 528b are aligned with the plurality of outer through-holes 226 of the showerhead plate 212. In accordance with examples of the disclosure, when the annular flow ring 214 is rotational positioned at the second position (as illustrated in FIG. 9) the gas conductance to the to the aligned exhaust channel (not shown) can be increased, relative to the first position, thereby allowing more rapid purging of the reaction chamber (in a subsequent step of process 700).

In accordance with examples of the disclosure, process 700 (FIG. 7) can further comprise purging the reaction chamber (step 708). In such examples, the excess process gas and any reaction byproducts can be rapidly exhausted from the reaction chamber. In such examples, the positioning of the annular flow ring 214 at the second position (as illustrated in FIG. 9) can create an increased conductance gas path between the reaction chamber and the exhaust channel (not shown) thereby increasing the purging efficiency of the reaction chamber.

In accordance with examples the disclosure, positioning the annular flow ring at the second position comprises actuating the actuator device 330 coupled to the annular flow ring 214 by an actuator coupling 328 disposed on a surface of the annular flow ring, as illustrated in FIG. 9. In such examples, the actuator device 330 can be configured to rotate the annular flow ring 214 about the ring central axis from the first position to the second position.

In accordance with examples of the disclosure, adjacent through-holes of the plurality of outer through-holes 226 (of the showerhead plates 212) are separated by a first arc length 430 (as illustrated in FIG. 8), and adjacent through-holes of the plurality of exhaust through-holes (528a and 528b) of the annular flow ring 214 are separated by a second arc length 530, wherein the second arc length is half of the first arc length. In such examples, positioning the annular flow ring 214 comprises rotating the annular flow ring 214 about the ring central axis 312 by the second arc length. In other words, moving the annular flow ring 214 from the first position to the second position comprises rotating the annular flow ring 214 by a rotational distance equal to the second arc length (i.e., the distance between adjacent exhaust through-holes of the annular flow ring 214).

In various embodiments and as illustrated in FIG. 8, the plurality of inner through-holes 224 of the showerhead plate 212 (through which process gas can be introduced into the reaction chamber) are unobstructed by the annular flow ring 214. In some embodiments, the obstruction of the plurality of inner through-holes 224 is accomplished by the annular flow ring 214 having an inner radius 322 which is greater than the radius of the inner region 308 of the showerhead plate 212.

In accordance with examples of the disclosure, process 700 (FIG. 7) can further comprise repeating the cycle of positioning the annular flow ring at the first position (step 702), introducing a process gas into the reaction chamber (step 704), positioning the annular flow ring at the second position (step 706), and purging the reaction chamber (step 708). In such examples, a cycle (as indicated by cycle loop 712) can be repeated one or more times, the number of repetitions being dependent on the process being performed within the reaction chamber.

In accordance with examples of the disclosure, the process being performed within the reaction chamber can comprise a cyclical process, such as, an atomic layer deposition process, for example. In such examples, the atomic layer deposition comprises a pulsing step. In the pulsing step process gas can be introduced into the reaction chamber. In some embodiments process 700 can therefore comprise positioning the annular flow ring at the first position (step 702) prior to performing a pulsing step of the atomic layer deposition process. In such examples, the atomic layer deposition can also comprise a purging step. In the purging step excess process gas and any reaction byproducts can be purged from the reaction chamber. In some embodiments process 700 can therefore comprise positioning the annular flow ring at the second position (step 706) prior to performing a purging step of the atomic layer deposition process.

In accordance with examples of the disclosure, the step of positioning of the annular flow ring at the first position (step 702) and the step of positioning the annular flow ring at the second position (step 706) can be initiated by a control system (such as control system 604 of FIG. 6). In such examples, the control system can be linked to the actuator device to initiate the positioning of the annular flow. In some embodiments, the control system is also linked with a valve manifold (such as valve manifold 108 of FIG. 6). In such embodiments, the control system can control one or more valves within the valve manifold for the initiating gas flow into reaction chamber. In some embodiments, the control system can synchronize the positioning of the annular flow ring (e.g., between the first position and the second position) with the control of the valve manifold such that the introduction of process gas into and out of the reaction chamber is synchronized with the positioning of the annular flow ring.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A showerhead assembly comprising:
a lid comprising an upper lid surface and a lower lid surface, the lower lid surface comprising an exhaust channel;
a showerhead plate disposed beneath the lid and having a plate central axis, the showerhead plate comprising:
a plurality of inner through-holes extending through the showerhead plate from an upper plate surface to a lower plate surface, the plurality of inner through-holes positioned in an inner region of the showerhead plate concentric to the plate central axis; and
a plurality of outer through-holes disposed in a concentric ring around the inner region and extending through the showerhead plate from the upper plate surface to the lower plate surface, the plurality of outer through-holes positioned at a first radial distance from the plate central axis; and
an annular flow ring disposed between the lid and the showerhead plate and having a ring central axis coincident with the plate central axis, the annular flow ring comprising:
a plurality of exhaust through-holes disposed in a concentric ring at the first radial distance from the ring central axis and extending through the annular flow ring from an upper ring surface to a lower ring surface;
wherein adjacent through-holes of the plurality of exhaust through-holes alternate in sequence between a first diameter and a second diameter, the first diameter being less than the second diameter.

2. The showerhead assembly of claim 1, wherein adjacent through-holes of the plurality of outer through-holes are separated by a first arc length, and adjacent through-holes of the plurality of exhaust through-holes are separated by a second arc length, wherein the second arc length is half the radial distance of the first arc length.

3. The showerhead assembly of claim 2, wherein the annular flow ring has an inner radius greater than a radius of the inner region of the showerhead plate.

4. The showerhead assembly of claim 3, wherein the exhaust channel of the lid, the plurality of outer through-holes of the showerhead plate, and the plurality of exhaust through-holes of the annular flow ring are radially aligned with each other.

5. The showerhead assembly of claim 4, wherein the annular flow ring further comprising an actuator coupling constructed and arranged to couple with an actuator device, the actuator device configured to rotate the annular flow ring about the ring central axis from a first position to a second position.

6. The showerhead assembly of claim 5, wherein the plurality of exhaust through-holes having the first diameter are configured to align with the plurality of outer through-holes of the showerhead plate at the first position, and the plurality of exhaust through-holes having the second diameter are configured to align with the plurality of outer through-holes of the showerhead plate at the second position.

7. A semiconductor processing system comprising:
a reaction chamber;
a showerhead assembly configured to regulate gas flow to and from the reaction chamber, the showerhead assembly comprising:
a lid comprising an upper lid surface and a lower lid surface, the upper lid surface comprising a main inlet configured to couple with a gas source, and the lower lid surface comprising an exhaust channel;
a showerhead plate disposed beneath the lid and having a plate central axis, the showerhead plate comprising:
a plurality of inner through-holes extending through the showerhead plate from an upper plate surface to a lower plate surface, the plurality of inner through-holes positioned in an inner region of the showerhead plate concentric to the plate central axis; and
a plurality of outer through-holes disposed in a concentric ring around the plurality of inner through-holes and extending through the showerhead plate from the upper plate surface to the lower plate surface, the plurality of outer through-holes positioned at a first radial distance from the plate central axis; and
an annular flow ring disposed between the lid and showerhead plate and having a ring central axis coincident with the plate central axis, the annular flow ring comprising:
an actuator coupling disposed on a surface of the annular flow ring; and
a plurality of exhaust through-holes disposed in a concentric ring at the first radial distance from the ring central axis and extending through the annular flow ring from an upper ring surface to a lower ring surface;
wherein the plurality of exhaust through-holes alternate in sequence between a first diameter and a second diameter, the first diameter being less than the second diameter;
an actuator device coupled to the actuator coupling, the actuator device configured to rotate the annular flow ring about the ring central axis from a first position to a second position;
a valve manifold constructed and arranged to control a supply of gas to the showerhead assembly from the gas source;
a vacuum assembly coupled to the exhaust channel and constructed and arranged for exhausting gas from the reaction chamber; and
a control system configured to synchronize the actuator device and a valve manifold.

8. The semiconductor processing system of claim 7, wherein adjacent through-holes of the plurality of outer through-holes are separated by a first arc length, and adjacent through-holes of the plurality of exhaust through-holes are separated by a second arc length, wherein the second arc length is half of the first arc length.

9. The semiconductor processing system of claim 8, wherein the annular flow ring has an inner radius greater than a radius of the inner region of the showerhead plate.

10. The semiconductor processing system of claim 9, wherein the exhaust channel, the plurality of outer through-holes of the showerhead plate, and the plurality of exhaust through-holes of the annular flow ring are radially aligned with each other.

11. The semiconductor processing system of claim 10, wherein the actuator device comprises an actuated two-state valve, wherein a first valve state positions the annular flow ring at the first position and a second valve state positions the annular flow ring at the second position.

12. The semiconductor processing system of claim 11, wherein the plurality of exhaust through-holes having the first diameter are configured to align with the plurality of outer through-holes of the showerhead plate at the first position, and the plurality of exhaust through-holes having the second diameter are configured to align with the plurality of outer through-holes of the showerhead plate at the second position.

13. A method of regulating gas flow to and from a reaction chamber when performing a process, the method comprising:
at a showerhead assembly comprising an annular flow ring disposed between a lid and a showerhead plate, the annular flow ring including a plurality of exhaust through-holes disposed in a concentric ring at a first radial distance from a ring central axis and extending through the annular flow ring from an upper ring surface to a lower ring surface, the plurality of exhaust through-holes alternating in sequence between a first diameter and a second diameter, the first diameter being less than the second diameter;
positioning the annular flow ring at a first position such that the first diameter through-holes are aligned with a plurality of outer through-holes extending through the showerhead plate;
introducing a process gas into the reaction chamber;
positioning the annular flow ring at a second position such that the second diameter through-holes are aligned with the plurality of outer through-holes extending through the showerhead plate; and
purging the reaction chamber.

14. The method of claim 13, wherein positioning the annular flow ring comprises actuating an actuator device coupled to the annular flow ring by an actuator coupling disposed on a surface of the annular flow ring, the actuator device configured to rotate the annular flow ring about the ring central axis from the first position to the second position.

15. The method of claim 14, wherein adjacent through-holes of the plurality of outer through-holes are separated by a first arc length, and adjacent through-holes of the plurality of exhaust through-holes are separated by a second arc length, wherein the second arc length is half of the first arc length.

16. The method of claim 15, wherein positioning the annular flow ring further comprises rotating the annular flow ring about the ring central axis by the second arc length.

17. The method of claim 16, wherein the steps of positioning the annular flow ring at the first position, introducing the process gas into the reaction chamber, positioning the annular flow ring at the second position, and purging the reaction chamber are performed one or more times.

18. The method of claim 17, wherein the process comprises an atomic layer deposition process.

19. The method of claim 18, further comprising positioning the annular flow ring at the first position prior to performing a pulsing step of the atomic layer deposition process.

20. The method of claim 18, further comprising positioning the annular flow ring at the second position prior to performing a pulsing step of the atomic layer deposition process.
